(19) United States
(12) Patent Application Publication
(10) Pub. No.: US 2004/0029047 A1
(43) Pub. Date: Feb. 12, 2004

(54) Micropattern forming material, micropattern forming method and method for manufacturing semiconductor device

(75) Inventors: Takeo Ishibashi, Tokyo (JP); Toshiyuki Toyoshima, Tokyo (JP); Mamoru Terai, Tokyo (JP); Shinji Tarutani, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/436,046

(22) Filed: May 13, 2003

(30) Foreign Application Priority Data
Aug. 7, 2002 (JP) 2002-230113

(51) Int. Cl. G03F 7/16; G03F 7/20; G03F 7/40; G03F 7/00

(52) U.S. Cl. 430/296; 430/311; 430/330; 430/328; 430/394; 430/315; 430/331

(57) ABSTRACT

A micropattern forming material comprises a polar change material formed on a resist pattern capable of generating an acid, the polar change material being soluble in water or an alkali, a portion of the polar change material in contact with the resist pattern undergoing a polar change caused by the acid from the resist pattern to form an insolubilized film insoluble in water and the alkali; and water or a mixed solvent of water and a water-soluble organic solvent.

### BACKGROUND OF THE INVENTION

1. Field of the Invention

The present invention relates to a micropattern forming material, a micropattern forming method and a method for manufacturing a semiconductor device.

2. Background Art

In recent years, as the degree of integration of semiconductor devices increases, the sizes of individual elements become increasingly smaller, along with smaller widths of wirings, gates and the like constituting individual elements. In general, a micropattern is formed by forming a desired resist pattern according to a photolithographic technique and etching different types of underlying thin films through the resist pattern as a mask. In this sense, the photolithographic technique is very important for the formation of the micropattern.

The photolithographic technique includes the steps of coating of a resist, positioning of a mask, light exposure and development. In this connection, however, with recent cutting-edge devices, the pattern dimension is now coming close in on the limit of resolution by light exposure, and thus it is imperative that an exposure technique of a higher degree of resolution be developed.

In convention photolithographic techniques, the shifting of the sensitivity of a resist toward a short wavelength side presents the problem that the etching resistance of the resist lowers. For instance, a resist having an aromatic ring in the molecule exhibits a good etching resistance, but with its sensitivity appearing at a long wavelength of 300 nm or over. On the other hand, a resist having no aromatic ring in the molecule has sensitivity at a short wavelength, but with a lowering of the etching resistance. If the etching resistance of a resist lowers, the resist film is more readily etched, with the attendant problem that the pattern accuracy of a finally formed thin film lowers.

We have disclosed in Japanese Patent No. 3071401 (corresponding U.S. Pat. No. 5,858,620) a method of forming a fine resist pattern where a water-soluble resin capable of crosslinkage by reaction with an acid catalyst is used to form a so-called organic frame on a resist surface. However, this method has the problem that the resultant resist pattern deforms through the internal stress caused by volumetric shrinkage of the resin in the course of the crosslinking reaction.

The invention has been made in order to overcome these problems in the art. An object of the invention to provide a micropattern forming material which ensures the formation of a micropattern beyond the limit of an exposure wavelength in a photolithographic technique, a micropattern forming method using the material, and a method for manufacturing a semiconductor device.

The invention also provides a micropattern forming material of a good resist resistance, a micropattern forming method using the material, and a method for manufacturing a semiconductor device.

The invention further provides a micropattern forming material which is freed of deformation of a resist pattern ascribed to the internal stress therein, a micropattern forming method using the same, and a method for manufacturing a semiconductor device.

Other objects and advantages of the invention will become apparent from the following description.

### SUMMARY OF THE INVENTION

According to one aspect of the present invention, a micropattern forming material comprises a polar change material formed on a resist pattern capable of generating an acid, the polar change material being soluble in water or an alkali, a portion of the polar change material in contact with the resist pattern undergoing a polar change caused by the acid from the resist pattern to form an insolubilized film insoluble in water and the alkali; and water or a mixed solvent of water and a water-soluble organic solvent.

According to another aspect of the present invention, in a micropattern forming method, a resist pattern capable of generating an acid is formed on a support. A micropattern forming material soluble in water or an alkali is coated on the resist pattern to form a micropattern forming film. The micropattern forming material includes (i) a polar change material soluble in water or the alkali undergoing a polar change caused by the acid, and (ii) water or a mixed solvent of water and a water-soluble organic solvent. An insolubilized film is formed by the polar change of the micropattern forming film caused by the acid from the resist pattern at a portion of the micropattern forming film in contact with the resist pattern. The insolubilized film is insoluble in water or the alkali. The remaining portion of the micropattern forming film which is soluble in water or the alkali is removed.

Other and further objects, features and advantages of the invention will appear more fully from the following description.

### BRIEF DESCRIPTION OF THE DRAWING

FIG. 1A shows a micropattern forming method according to the first embodiment.

FIG. 1B shows a micropattern forming method according to the first embodiment.

FIG. 1C shows a micropattern forming method according to the first embodiment.

FIG. 1D shows a micropattern forming method according to the first embodiment.

FIG. 1E shows a micropattern forming method according to the first embodiment.

FIG. 1F shows a micropattern forming method according to the first embodiment.

FIG. 2A shows a micropattern forming method according to the second embodiment.

FIG. 2B shows a micropattern forming method according to the second embodiment.

FIG. 2C shows a micropattern forming method according to the second embodiment.

FIG. 2D shows a micropattern forming method according to the second embodiment.

FIG. 2E shows a micropattern forming method according to the second embodiment.

FIG. 2F shows a micropattern forming method according to the second embodiment.

FIG. 2G shows a micropattern forming method according to the second embodiment.

FIG. 3A shows a micropattern forming method according to the third embodiment.

FIG. 3B shows a micropattern forming method according to the third embodiment.

FIG. 3C shows a micropattern forming method according to the third embodiment.

FIG. 3D shows a micropattern forming method according to the third embodiment.

FIG. 3E shows a micropattern forming method according to the third embodiment.

FIG. 3F shows a micropattern forming method according to the third embodiment.

FIG. 3G shows a micropattern forming method according to the third embodiment.

FIG. 4 is a plan view of the example 9 or 10.

### DETAILED DESCRIPTION OF THE PREFERRED EMBODIMENTS

The embodiments of the invention are described in detail with reference to the accompanying drawings.

First Embodiment

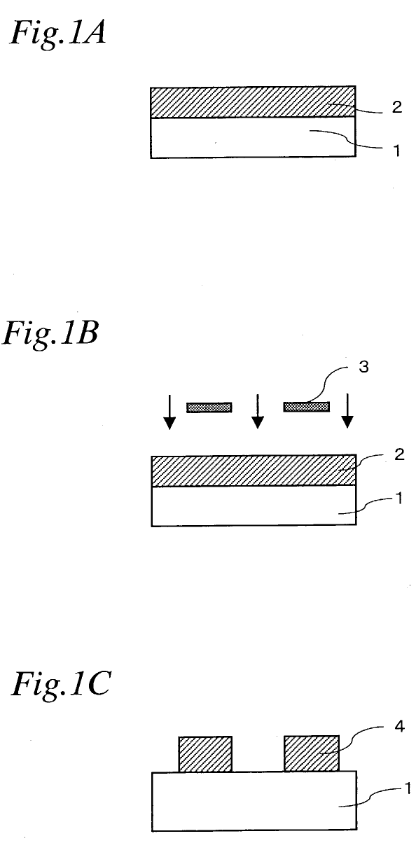

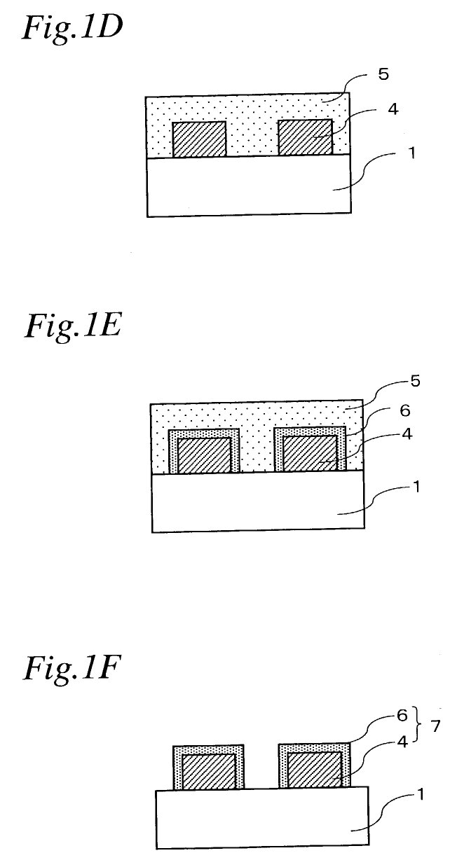

FIG. 1A˜FIG. 1F is, respectively, a process chart showing a method of manufacturing a semiconductor device using a micropattern forming material according to the invention.

As shown in FIG. 1A, a resist composition is coated on a semiconductor substrate 1 to form a resin film 2. For instance, a resist composition is coated on a semiconductor substrate by a spin coating method or the like in a thickness of 0.7 μm to 1.0 μm.

In this embodiment, the resist composition used is one which is able to generate an acidic component inside the resist by application of heat. The composition includes, for example, a positive-type resist made of a novolac resin and a naphthoquinone diazide photosensitizer. The resist composition may be either a positive-type resist or a negative-type resist.

Next, the solvent present in the resist film 2 is evaporated by a pre-baking treatment. The pre-baking treatment is carried out, for example, by thermal treatment using a hot plate at 70° C. to 110° C. for about 1 minute. Thereafter, as shown in FIG. 1B, the resist film 2 is exposed to light through a mask 3. The light source used for the exposure may be one whose wavelength corresponds to a sensitivity wavelength of the resist film 2. Using such a light source, the resist film 2 is irradiated, for example, with a g-line spectrum of light, an i-line spectrum of light, deep UV light, a KrF excimer laser beam (248 nm), an ArF excimer laser beam (193 nm) and EB (electron beam), or an X ray.

After exposure of the resist film, a PEB treatment (post-exposure baking treatment) is carried out, if necessary. This leads to an improved resolution of the resist film. The PEB treatment is performed, for example, by baking at 50° C. to 120° C.

Next, developing treatment is carried out by use of an appropriate liquid developer for patterning of the resist film. If the resist composition used is of the positive type, such a resist pattern 4 as shown in FIG. 1C is obtained. For a liquid developer, an alkaline aqueous solution containing, for example, about 0.05 to 3.0 wt % of TMAH (tetramethylammonium hydroxide) may be used.

After completion of the development, post-development baking may be performed, if necessary. Because the post-development baking influences a subsequent mixing reaction, it is favorable that temperature conditions are appropriately set depending on the types of resist composition and micropattern-forming material used. For instance, a hot plate is used for heating at 60° C. to 120° C. for about 60 seconds.

As shown in FIG. 1D, a micropattern forming material according to the invention is coated onto the resist pattern 4 to form a micropattern forming film 5. The manner of coating the micropattern forming material is not critical so far as uniform coating on the resist pattern 4 is ensured. For instance, a spraying method, a spin coating method or a dipping method can be used for the coating.

The micropattern forming material of the invention has a feature in that it undergoes a polar change in the presence of an acid and is insolubilized in a liquid developer. More particularly, the insolubilization is realized by utilizing pinacol rearrangement with an acid. The composition of the micropattern forming material is described in detail below.

The micropattern forming material according to the invention comprises a water or alkali-soluble resin, a pinacol, and water or a mixed solvent of water and an water-soluble organic solvent.

The resins include, for example, ones having an aromatic ring in the structure thereof. The resins may be used singly or in admixture of two or more resins. For instance, mentions is made of polyvinyl alcohol, polyacrylic acid, polyvinyl acetal, polyvinyl pyrrolidone, polyethyleneimine, polyethylene oxide, a styrene-maleic anhydride copolymer, polyvinylamine, polyallylamine, an oxazoline group-containing water-soluble resin, a water-soluble melamine resin, a water-soluble urea resin, an alkyd resin or sulfonamide.

The pinacol is represented by chemical formula 1 and includes, for example, 1,1,2,2-tetramethylethylene glycol, hydrobenzoin, benzopinacol, DL-α,β-di-(4-pyridyl)glycol or 2,3-di-2-pyridyl-2,3-butanediol as shown in chemical formula 2.

[Chemical Formula 1]

R₁R₂C(OH)C(OH)R₃R₄

(wherein R₁, R₂, R₃ and R₄ represent hydrogen, an alkyl group, a phenyl group or a pyridine group).

[Chemical Formula 2]

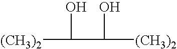

1,1,2,2-Tetramethylethylene glycol

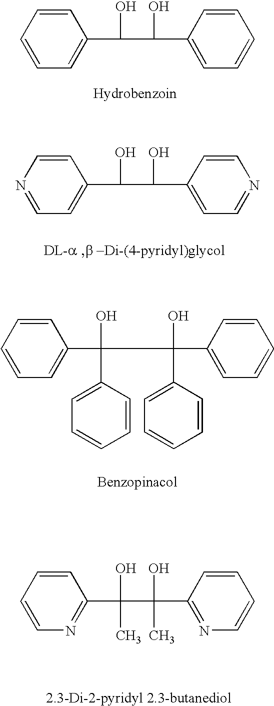

The resin and pinacol may be dissolved either in water or in a mixed solvent of water and an organic solvent. The organic solvent mixed with water is not critical in type so far as it is miscible with water, and the type of organic solvent should be so selected as to take the solubility of the resin used for the micropattern forming material into consideration and should be mixed within a range of amount not dissolving a resist pattern. For instance, alcohols such as ethanol, methanol, isopropyl alcohol and cyclohexanol, γ-butyrolactone, N-methylpyrrolidone or acetone can be used.

The micropattern forming material may be one which comprises a pinacol component-containing copolymer soluble in water or alkali, and water or a mixed solvent of water and a water-soluble organic solvent. For the pinacol component-containing, water or alkali-soluble copolymer, a copolymer of p-(1,2-dihydroxy-1,2-dimethylpropyl)styrene and a styrene derivative having a hydrophilic group may be used.

For instance, as shown in chemical formula 3, a copolymer of p-(1,2-dihydroxy-1,2-dimethylpropyl)styrene and tetramethylammonium-p-styrenesulfonate, or a copolymer of p-(1,2-dihydroxy-1,2-dimethylpropyl)styrene and styrene having an ethylene oxide oligomer at the para position may be used as a major component of the copolymer. The ethylene oxide oligomer should preferably be such that n=10˜30. In addition, a copolymer made of three components of p-(1,2-dihydroxy-1,2-dimethylpropyl)styrene, tetramethylammonium-p-styrenesulfonate and styrene having an ethylene oxide oligomer at the para position may also be used as the major component.

[Chemical Formula 3]

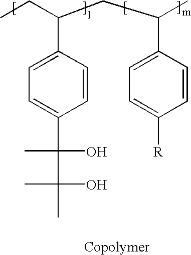

R=^{-SO}^{₃}^{⁻⁺}^{N(CH}^{₃}⁾⁴ or

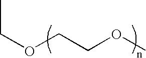

For the styrene derivative having a hydrophilic group, there may be used a styrene derivative having ammonium sulfonate or ethylene oxide oligomer at the ortho or meta position.

In this case, p-(1,2-dihydroxy-1,2-dimethylpropyl)styrene serves as a pinacol component. Tetramethylammonium-p-styrenesulfonate and styrene having an ethylene oxide oligomer at the para position, respectively, plays the role of imparting hydrophilicity and also adhesion to a resist.

Where the hydrophilic components of tetramethylammonium-p-styrenesulfonate and styrene having an ethylene oxide oligomer at the para position are used for copolymerization with p-(1,2-dihydroxy-1,2-dimethylpropyl)styrene, tetramethylammonium-p-styrenesulfonate may be larger in amount than styrene having an ethylene oxide oligomer at the para position, and vice versa. Alternatively, tetramethylammonium-p-styrenesulfonate and styrene having an ethylene oxide oligomer at the para position may be used in equal amounts. It is preferred that the mixing ratio is changed depending on the properties of a resist used.

Moreover, the micropattern forming material of the invention may further comprise, aside form the above-stated components, other components as additives. For instance, for the purpose of improving coating properties, a surface active agent may be contained.

Next, pre-baking treatment is carried out so as to evaporate the solvent from the micropattern forming film 5. The pre-baking treatment is effected, for example, by use of a hot plate for thermal treatment at about 85° C. for about 1 minute.

After the pre-baking treatment, the resist pattern 4 formed on the semiconductor substrate 1 and the micropattern forming film 5 formed thereon are subjected to thermal treatment (mixing bake treatment, which is hereinafter referred to as MB treatment). For example, a hot plate is used to carry out the MB treatment at 70° C. to 150° C. for 60 seconds to 120 seconds.

When the MB treatment is carried out, an acid is generated in the resist pattern and the diffusion of the acid is facilitated, thereby feeding the acid from the resist pattern to the micropattern forming film. Upon the feed of the acid to the micropattern forming film, the pinacol component present in the micropattern forming film undergoes a polar change by the pinacol rearrangement in the presence of the acid in the vicinity of the interface between the resist pattern and the micropattern forming film. This causes the polarity of the micropattern forming film to be changed, so that the micropattern forming film is insolubilized in water or an alkaline aqueous developer. On the other hand, any polar change by the pinacol rearrangement does not take place in the micropattern forming film at regions thereof other than the vicinity of the interface with the resist pattern, and these regions remain soluble in water or an alkaline aqueous developer.

As set forth hereinabove, the invention is characterized in that the polar change ascribed to the pinacol rearrangement is utilized to form a portion or portions (hereinafter referred to as insolubilized layer) insolubilized in a liquid developer within the micropattern forming film. As shown in FIG. 1E, the insolubilized layer 6 is formed in the micropattern forming film 5 so as to cover the resist pattern 4 therewith.

The thickness of the insolubilized layer can be controlled not only by changing the conditions of the MB treatment, but also by changing the quantity of reaction between the resist pattern and the micropattern forming material.

For instance, where the micropattern forming material used is one which is obtained by dissolving a pinacol-containing, water-soluble resin in water, the thickness of the insolubilized layer can be controlled by changing the mixing ratio of the resin and the pinacol.

Alternatively, when the micropattern forming material used is one which is obtained by dissolving a copolymer made of a water-soluble resin of two or more monomers in water, the thickness of the insolubilized layer can be appropriately controlled by changing the copolymerizing ratio between the pinacol component and the other component constituting the copolymer. For example, where a copolymer of p-(1,2-dihydroxy-1,2-dimethylpropyl)styrene and tetramethylammonium-p-styrenesulfonate is used as major component of the micropattern forming material, the copolymerization ratio therebetween is appropriately selected to control the quantity of reaction between the resist pattern and the micropattern forming film. In this case, the pinacol component in the copolymer should preferably be within as range of 55 mole % to 75 mole %.

Next, development treatment is carried out using water or an alkaline aqueous developer to remove the micropattern forming film 5 at portions where not insolubilized. For the alkaline aqueous developer, an aqueous solution of an alkali such as TMAH (tetramethylammonium hydroxide) can be used. After the development, post-baking treatment is performed under appropriate conditions to form a micropattern 7, thereby providing a structure of FIG. 1F. The post-baking treatment can be carried out, for example, by heating at 90° C. to 110° C. for 70 seconds to 90 seconds.

The micropattern formed according to the foregoing steps is provided as a mask to etch different types of thin films, such as an insulating film, formed on the underlying semiconductor substrate or semiconductor substrate, to fabricate semiconductor devices having different types of micropattern structures.

According to this embodiment, after the micropattern forming film has been insolubilized at the interface between the resist pattern and the micropattern forming film, the micropattern forming film at portions which remain non-insolubilized is removed, so that a micropattern can be formed beyond the limit of an exposure wavelength. The insolubilization of the micropattern forming film does not take place through crosslinking reaction with the resist pattern, but is realized by using the polar change caused by the pinacol rearrangement. Accordingly, the internal stress occurring inside the resist can be reduced and the resist pattern is prevented from deforming.

Moreover, according to this embodiment, an aromatic ring-containing micropattern forming film is formed on the resist pattern so as to cover the resist pattern therewith. Accordingly, when an underlying thin film is etched through this micropattern used as a mask, the resist pattern can be prevented from attacking with an etchant. More particularly, where a resist film having sensitivity at a short wavelength is used, there is no possibility of the resist film being attacked with an etchant, thereby ensuring the formation of a pattern of high accuracy in the underlying thin film.

Second Embodiment

This embodiment is characterized in that light exposure is carried out prior to the MB treatment set out in the first embodiment.

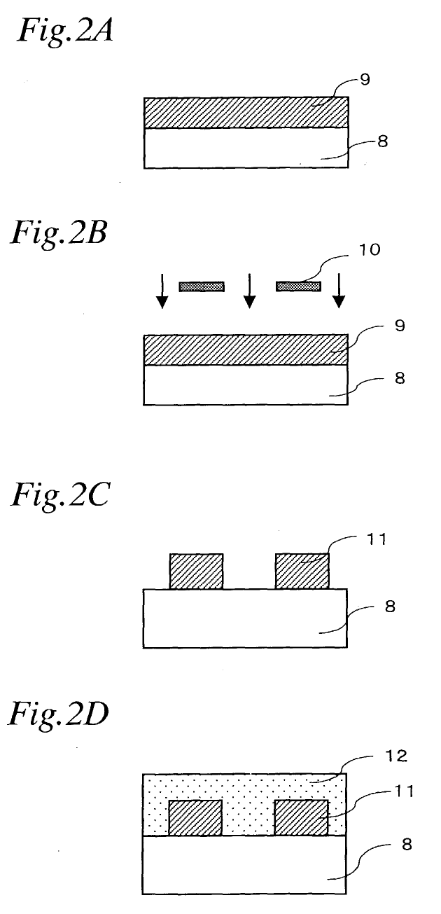

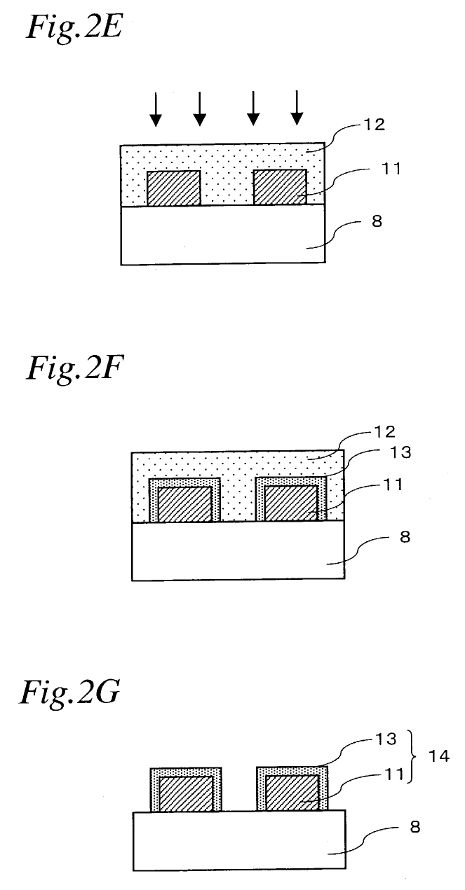

FIG. 2A˜FIG. 2G, respectively, is a process chart showing a method of manufacturing a semiconductor device using a micropattern forming material according to the invention.

As shown in FIG. 2A, a resist composition is coated onto a semiconductor substrate 8 to from a resist film 9. For instance, a resist composition is coated onto a semiconductor substrate by a spin coating method or the like in a thickness of 0.7 μm to 1.0 μm, In this embodiment, the resist composition used is one which is able to generate an acidic component inside the resist by application of heat. The resist composition includes, for example, a positive type resist constituted of a novolac resin and a naphthoquinone diazide photosensitizer. Alternatively, a chemical amplification-type resist which generates an acid by irradiation of a UV ray or the like may also be used. The resist composition may be either of a positive type resist or a negative type resist.

Next, the solvent present in the resist film 9 is evaporated by a pre-baking treatment. The pre-baking treatment is carried out, for example, by thermal treatment using a hot plate at 70° C. to 110° C. for about 1 minute. Thereafter, as shown in FIG. 2B, the resist film 9 is exposed to light through a mask 10. The light source used for the exposure may be one whose wavelength corresponds to a sensitivity wavelength of the resist film 9. Using such a light source, the resist film 9 is irradiated, for example, with a g-line spectrum, an i-line spectrum, deep UV light, a KrF excimer laser beam (248 nm), an ArF excimer laser beam (193 nm) and EB (electron beam), or an X ray.

After exposure of the resist film, a PEB treatment (post-exposure baking treatment) is carried out, if necessary. This leads to an improved resolution of the resist film. The PEB treatment is performed, for example, by baking at 50° C. to 120° C.

Next, developing treatment is carried out by use of an appropriate liquid developer for patterning of the resist film. If the resist composition used is of the positive type, such a resist pattern 11 as shown in FIG. 2C is obtained. For a liquid developer, an alkaline aqueous solution containing, for example, about 0.05 to 3.0 wt % of TMAH (tetramethylammonium hydroxide) may be used.

After completion of the development, post-development baking may be performed, if necessary. Because the post-development baking influences a subsequent mixing reaction, it is favorable that temperature conditions are appropriately set depending on the types of resist composition and micropattern-forming material used. For instance, a hot plate is used for heating at 60° C. to 120° C. for about 60 seconds.

As shown in FIG. 2D, a micropattern forming material according to the invention is coated onto the resist pattern 11 to form a micropattern forming film 12. The manner of coating the micropattern forming material is not critical so far as uniform coating on the resist pattern 11 is ensured. For instance, a spraying method, a spin coating method or a dipping method can be used for the coating.

The micropattern forming material of the invention has a feature in that it undergoes polar change in the presence of an acid and is insolubilized in a liquid developer. More particularly, the insolubilization is realized by utilizing pinacol rearrangement with an acid. The composition of the micropattern forming material is described in detail below.

The micropattern forming material according to the invention comprises, like the first embodiment, a water or alkali-soluble resin, a pinacol and water or a mixed solvent of water and an organic solvent miscible with water.

The resins include, for example, ones having an aromatic ring in the structure thereof. The resins may be used singly or in admixture of two or more resins. For instance, mentions is made of polyvinyl alcohol, polyacrylic acid, polyvinyl acetal, polyvinyl pyrrolidone, polyethyleneimine, polyethylene oxide, a styrene-maleic anhydride copolymer, polyvinylamine, polyallylamine, an oxazoline group-containing water-soluble resin, a water-soluble melamine resin, a water-soluble urea resin, an alkyd resin or sulfonamide.

The pinacol includes, for example, 1,1,2,2-tetramethylethylene glycol, hydrobenzoin, benzopinacol, DL-α,β-di-(4-pyridyl)glycol or 2,3-di-2-pyridyl-2,3-butanediol The resin and pinacol may be dissolved either in water or in a mixed solvent of water and an organic solvent. The organic solvent mixed with water is not critical in type so far as it is miscible with water, and the type of organic solvent should be so selected as to take the solubility of the resin used for the micropattern forming material into consideration and should be mixed within a range of amount not dissolving a resist pattern. For instance, alcohols such as ethanol, methanol, isopropyl alcohol and cyclohexanol, γ-butyrolactone, N-methylpyrrolidone or acetone can be used.

The micropattern forming material may be one which comprises a pinacol component-containing copolymer soluble in water or alkali, and water or a mixed solvent of water and a water-soluble organic solvent. For the pinacol component-containing, water or alkali-soluble copolymer, a copolymer of p-(1,2-dihydroxy-1,2-dimethylpropyl)styrene and a styrene derivative having a hydrophilic group may be used.

For instance, a copolymer of p-(1,2-dihydroxy-1,2-dimethylpropyl)styrene and tetramethylammonium-p-styrenesulfonate or a copolymer of p-(1,2-dihydroxy-1,2-dimethylpropyl)styrene and styrene having an ethylene oxide oligomer at the para position may be used as a major component of the copolymer as shown in the foregoing chemical formula 3. The ethylene oxide oligomer should preferable be such that n=10˜30. In addition, a copolymer made of three components of p-(1,2-dihydroxy-1,2-dimethylpropyl)styrene, tetramethylammonium-p-styrenesulfonate and styrene having an ethylene oxide oligomer at the para position may also be used as the major component.

In this case, p-(1,2-dihydroxy-1,2-dimethylpropyl)styrene serves as a pinacol component. Tetramethylammonium-p-styrenesulfonate and styrene having an ethylene oxide oligomer at the para position, respectively, plays the role of imparting hydrophilicity and also adhesion to a resist.

Where the hydrophilic components of tetramethylammonium-p-styrenesulfonate and styrene having an ethylene oxide oligomer at the para position are used for copolymerization with p-(1,2-dihydroxy-1,2-dimethylpropyl)styrene, tetramethylammonium-p-styrenesulfonate may be larger in amount than styrene having an ethylene oxide oligomer at the para position, and vice versa. Alternatively, tetramethylammonium-p-styrenesulfonate and styrene having an ethylene oxide oligomer at the para position may be used in equal amounts. It is preferred that the mixing ratio is changed depending on the properties of a resist used.

A styrene derivative wherein ammonium sulfonate or an ethylene oxide oligomer is bonded to styrene at the ortho or meta position may be used as the styrene derivative having a hydrophilic group.

Moreover, the micropattern forming material of the invention may further comprise, aside form the above-stated components, other components as additives. For instance, for the purpose of improving coating properties, a surface active agent may be contained.

Next, pre-baking treatment is carried out so as to evaporate the solvent from the micropattern forming film 12. The pre-baking treatment is effected, for example, by use of a hot plate for thermal treatment at about 85° C. for about 1 minute.

As shown in FIG. 2E, this embodiment is characterized in that after the pre-baking treatment, the semiconductor substrate 8 is exposed to light over the entire surfaces thereof. This permits an acid to be generated in the resist pattern prior to the MB treatment. The light source used for the exposure is not critical so far as it ensures acid generation in the resist pattern and is appropriately selected depending on the sensitivity wavelength of the resist pattern. For examples, the exposure is possible when using an Hg lamp, a KrF excimer laser, an ArF excimer laser or the like.

Next, the resist pattern 11 formed on the semiconductor substrate 8 and the micropattern forming film 12 formed thereon are subjected to the MB treatment. The diffusion of an acid is facilitated by the MB treatment, thereby feeding the acid from the resist pattern to the micropattern forming film. Upon the feed of the acid to the micropattern forming film, a polar change takes place at the interface between the resist pattern and the micropattern forming film, thereby causing the micropattern forming film to be insolubilized. The MB treatment is set under optimum conditions depending on the type of resist composition and the required thickness of the insolubilized layer. For instance, a hot plate is used to create MB treating conditions of 70° C. to 150° C. and 60 seconds to 120 seconds. When the MB treatment is carried out, the insolubilized layer 13 caused by the polar change is formed in the micropattern forming film 12 so as to cover the resist pattern 11 therewith as is particularly shown in FIG. 2F.

The thickness of the insolubilized layer can be changed by controlling the quantity of reaction between the resist pattern and the micropattern forming material, and a specific method thereof is similar to that of the first embodiment.

Next, development treatment is carried out using water or an alkaline aqueous developer to remove the micropattern forming film 12 at portions where not insolubilized. For the alkaline aqueous developer, an aqueous solution of an alkali such as TMAH (tetramethylammonium hydroxide) can be used. After the development, post-baking treatment is performed under appropriate conditions to form a micropattern 14, thereby providing a structure of FIG. 2G. The post-baking treatment can be carried out, for example, by heating at 90° C. to 110° C. for 70 seconds to 90 seconds.

The micropattern formed according to the foregoing steps is provided as a mask to etch different types of thin films, such as an insulating film, formed on the underlying semiconductor substrate or semiconductor substrate, to fabricate semiconductor devices having different types of micropattern structures.

According to this embodiment, aside from the effects obtained in the first embodiment, the exposure is carried out prior to the MB treatment, so that the insolubilization reaction of the micropattern forming film can be more facilitated. More particularly, the insolubilized layer can be formed more thickly, enabling one to form a finer pattern.

Third Embodiment

This embodiment is characterized in that after the formation of a resist pattern, an electron beam is irradiated over a desired region of a semiconductor substrate.

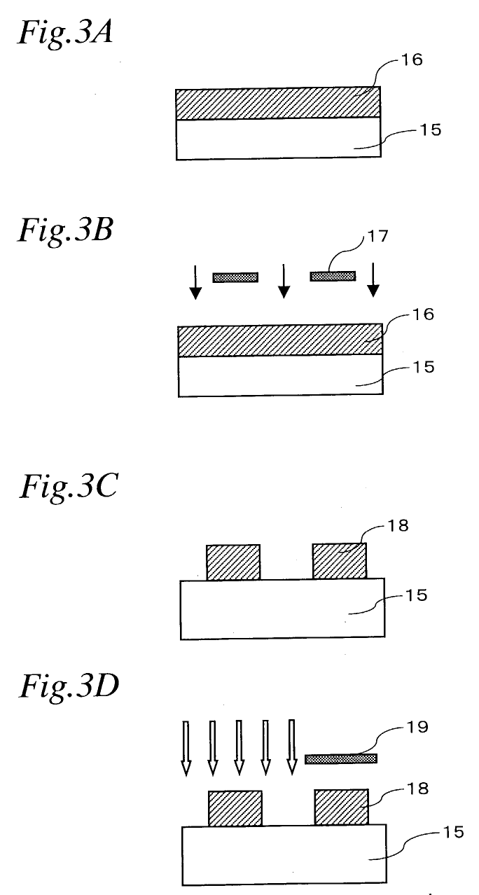

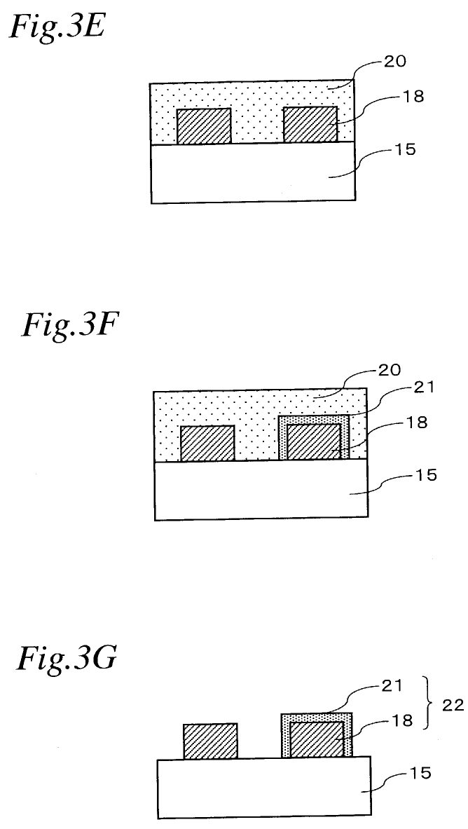

FIG. 3A˜3G, respectively, is a process chart showing a method of manufacturing a semiconductor device using a micropattern forming material according to the invention.

As shown in FIG. 3A, a resist composition is coated onto a semiconductor substrate 15 to form a resist film 16. For instance, a resist composition is coated onto a semiconductor substrate by a spin coating method or the like in a thickness of 0.7 μm to 1.0 μm,

In this embodiment, the resist composition used is one which is able to generate an acidic component inside the resist by application of heat. The resist composition includes, for example, a positive type resist constituted of a novolac resin and a naphthoquinone diazide photosensitizer. The resist composition may be either of a positive type resist or a negative type resist.

Next, the solvent present in the resist film 16 is evaporated by a pre-baking treatment. The pre-baking treatment is carried out, for example, by thermal treatment using a hot plate at 70° C. to 110° C. for about 1 minute. Thereafter, as shown in FIG. 3B, the resist film 16 is exposed to light through a mask 17. The light source used for the exposure may be one whose wavelength corresponds to a sensitivity wavelength of the resist film 16. Using such a light source, the resist film 9 is irradiated, for example, with a g-line spectrum, an i-line spectrum, deep UV light, a KrF excimer laser beam (248 nm), an ArF excimer laser beam (193 nm) and EB (electron beam), or an X ray.

After exposure of the resist film, a PEB treatment (post-exposure baking treatment) is carried out, if necessary. This leads to an improved resolution of the resist film. The PEB treatment is performed, for example, by baking at 50° C. to 120° C.

Next, developing treatment is carried out by use of an appropriate liquid developer for patterning of the resist film. If the resist composition used is of the positive type, such a resist pattern 18 as shown in FIG. 3C is obtained. For a liquid developer, an alkaline aqueous solution containing, for example, about 0.05 to 3.0 wt % of TMAH (tetramethylammonium hydroxide) may be used.

After completion of the development, post-development baking may be performed, if necessary. Because the post-development baking influences a subsequent mixing reaction, it is favorable that temperature conditions are appropriately set depending on the types of resist composition and micropattern-forming material used. For instance, a hot plate is used for heating at 60° C. to 120° C. for about 60 seconds.

This embodiment is characterized in that after the formation of the resist pattern, the semiconductor substrate 15 is selectively irradiated with an electron beam as shown in FIG. 3D. More particularly, the selected regions of the semiconductor substrate 15 are covered with a mask 19 which shields an electron beam, and the other regions are irradiated with an electron beam.

Next, as shown in FIG. 3E, a micropattern forming material is coated onto the resist pattern 18 to form a micropattern forming film 20. The manner of coating the micropattern forming material is not critical so far as uniform coating on the resist pattern 18 is ensured. For instance, a spraying method, a spin coating method or a dipping method can be used for the coating.

The micropattern forming material of the invention has a feature in that it undergoes polar change in the presence of an acid and is insolubilized in a liquid developer. More particularly, the insolubilization is realized by utilizing pinacol rearrangement with an acid. The composition of the micropattern forming material is described in detail below.

The micropattern forming material according to the invention comprises, like the first embodiment, a water or alkali-soluble resin, a pinacol and water or a mixed solvent of water and a water-soluble organic solvent.

For the resins, for example, those having an aromatic ring in the structure thereof may be used. The resins may be used singly or in admixture of two or more resins. For instance, mentions is made of polyvinyl alcohol, polyacrylic acid, polyvinyl acetal, polyvinyl pyrrolidone, polyethyleneimine, polyethylene oxide, a styrene-maleic anhydride copolymer, polyvinylamine, polyallylamine, an oxazoline group-containing water-soluble resin, a water-soluble melamine resin, a water-soluble urea resin, an alkyd resin or sulfonamide.

The pinacol includes, for example, 1,1,2,2-tetramethylethylene glycol, hydrobenzoin, benzopinacol, DL-α,β-di-(4-pyridyl)glycol or 2,3-di-2-pyridyl-2,3-butanediol.

The resin and pinacol may be dissolved either in water or in a mixed solvent of water and an organic solvent. The organic solvent mixed with water is not critical in type so far as it is miscible with water, and the type of organic solvent should be so selected as to take the solubility of the resin used for the micropattern forming material into consideration and should be mixed within a range of amount not dissolving a resist pattern. For instance, alcohols such as ethanol, methanol, isopropyl alcohol and cyclohexanol, γ-butyrolactone, N-methylpyrrolidone or acetone can be used.

The micropattern forming material may be one which comprises a pinacol component-containing copolymer soluble in water or alkali, and water or a mixed solvent of water and a water-soluble organic solvent. For the pinacol component-containing, water or alkali-soluble copolymer, a copolymer of p-(1,2-dihydroxy-1,2-dimethylpropyl)styrene and a styrene derivative having a hydrophilic group may be used.

For instance, a copolymer of p-(1,2-dihydroxy-1,2-dimethylpropyl)styrene and tetramethylammonium-p-styrenesulfonate or a copolymer of p-(1,2-dihydroxy-1,2-dimethylpropyl)styrene and styrene having an ethylene oxide oligomer at the para position may be used as a major component of the copolymer as shown in the foregoing chemical formula 3. The ethylene oxide oligomer should preferable be such that n=10˜30. In addition, a copolymer made of three components of p-(1,2-dihydroxy-1,2-dimethylpropyl)styrene, tetramethylammonium-p-styrenesulfonate and styrene having an ethylene oxide oligomer at the para position may also be used as the major component.

In this case, p-(1,2-dihydroxy-1,2-dimethylpropyl)styrene serves as a pinacol component. Tetramethylammonium-p-styrenesulfonate and styrene having an ethylene oxide oligomer at the para position, respectively, plays the role of imparting hydrophilicity and also adhesion to a resist.

Where the hydrophilic components of tetramethylammonium-p-styrenesulfonate and styrene having an ethylene oxide oligomer at the para position are used for copolymerization with p-(1,2-dihydroxy-1,2-dimethylpropyl)styrene, tetramethylammonium-p-styrenesulfonate may be larger in amount than styrene having an ethylene oxide oligomer at the para position, and vice versa. Alternatively, tetramethylammonium-p-styrenesulfonate and styrene having an ethylene oxide oligomer at the para position may be used in equal amounts. It is preferred that the mixing ratio is changed depending on the properties of a resist used.

It will be noted that a styrene derivative wherein ammonium sulfonate or an ethylene oxide oligomer is bonded to styrene at the ortho or meta position may be used as the styrene derivative having a hydrophilic group.

Moreover, the micropattern forming material of the invention may further comprise, aside form the above-stated components, other components as additives. For instance, for the purpose of improving coating properties, a surface active agent may be contained.

Next, pre-baking treatment is carried out so as to evaporate the solvent from the micropattern forming film 20. The pre-baking treatment is effected, for example, by use of a hot plate for thermal treatment at about 85° C. for about 1 minute.

After the pre-baking treatment, the resist pattern 18 formed on the semiconductor substrate 15 and the micropattern forming film 20 formed thereof are subjected to the MB treatment. Upon the MB treatment, as shown in FIG. 3F, the insolubilization reaction does not occur at the portions where selectively irradiated with an electron beam, but an insolubilized layer 21 is formed only on portions where not irradiate with the electron beam. That is, the insolubilized layer 21 is formed so as to cover the resist pattern 18 therewith only in the micropattern forming film 20 at portions thereof where the electron beam is not irradiated by shielding with the electron beam shield.

The MB treatment is set under optimum conditions depending on the type of resist composition and the required thickness of the insolubilized layer. For instance, a hot plate is used to create MB treating conditions of 70° C. to 150° C. and 60 seconds to 120 seconds.

The thickness of the insolubilized layer can be changed by controlling the quantity of reaction between the resist pattern and the micropattern forming film, and a specific method thereof is similar to that of the first embodiment.

Next, development treatment is carried out using water or an alkaline aqueous developer to remove the micropattern forming film 20 at portions where not insolubilized. For the alkaline aqueous developer, an aqueous solution of an alkali such as TMAH (tetramethylammonium hydroxide) can be used. After the development, post-baking treatment is performed under appropriate conditions to form a micropattern 22, thereby providing a structure of FIG. 3G. The post-baking treatment can be carried out, for example, by heating at 90° C. to 110° C. for 70 seconds to 90 seconds.

The micropattern formed according to the foregoing steps is provided as a mask to etch different types of thin films, such as an insulating film, formed on the underlying semiconductor substrate or semiconductor substrate, to fabricate semiconductor devices having different types of micropattern structures.

According to this embodiment, an electron beam is irradiated on only selected regions of a semiconductor substrate, so that the insolubilized layer is not formed only on the selected regions. Accordingly, micropatterns of different sizes can be formed on the same semiconductor substrate.

In this embodiment, irradiation of an electron beam only on specific regions has been described, to which the invention is not limited. For instance, in case of a resist pattern capable of generating an acid by exposure, after formation of a micropattern forming film, part of a semiconductor substrate may be shielded by a mask to irradiate light only onto selected regions. This allows an insolubilized layer to be formed only at the exposed portions.

In Embodiments 1 to 3, as the instances of a resist composition, a resist capable generating an acid by application of heat and a chemically amplified resist capable of generating an acid by irradiation of a UV ray or the like are mentioned, which the invention should not be construed as limitation thereof. For example, a resist composition, which contains an acidic substance such as a carboxylic acid and is so arranged that this acidic substance is diffused by heating, may also be used.

Alternatively, a resist pattern may be surface-treated with an acidic liquid or an acidic gas. According to this method, the acid soaks in the resist pattern and an acid-containing thin layer can be formed in the surface of the resist pattern, with a similar effect being obtained.

Moreover, in Embodiments 1 to 3, the cases where a micropattern is formed on a semiconductor substrate have been illustrated, to which the invention is not limited. The micropattern may be formed on other type of support so far as use is made of the formation of a micropattern.

Formation of Resist Pattern

### Example 1

A novolac resin and naphthoquinone diazide were dissolved in a solvent consisting of ethyl lactate and propylene glycol monoethyl acetate to prepare an i-line resist, which was provided as a resist composition. Next, the resist composition was dropped on a silicon wafer and spin coated by use of a spinner. Thereafter, pre-baking was carried out at 85° C. for 70 seconds to evaporate the solvent from the first resist film. The resist film after the pre-baking had a thickness of about 0.1 μm.

Next, the resist film was exposed to light by use of an i-line reduced projection-type aligner. Thereafter, the PEB treatment was carried out at 120° C. for 70 seconds, followed by development with an alkaline aqueous developer (HMD3, made by Tokyo Ohka Kogyo Co., Ltd.) to obtain a resist pattern.

### Example 2

A novolac resin and naphthoquinone diazide were dissolved in a solvent of 2-heptane to prepare an i-line resist, which was provided as a resist composition. Next, the resist composition was dropped on a silicon wafer and spin coated by use of a spinner. Thereafter, pre-baking was carried out at 85° C. for 70 seconds to evaporate the solvent from the resist film. The resist film after the pre-baking had a thickness of about 0.8 μm.

Next, the resist film was exposed to light by use of an i-line reduced projection-type aligner. Thereafter, the PEB treatment was carried out at 120° C. for 70 seconds, followed by development with an alkaline aqueous developer (HMD3, made by Tokyo Ohka Kogyo Co., Ltd.) to obtain a resist pattern.

### Example 3

A novolac resin and naphthoquinone diazide were dissolved in a solvent consisting of ethyl lactate and butyl acetate to prepare an i-line resist, which was provided as a resist composition. Next, the resist composition was dropped on a silicon wafer and spin coated by use of a spinner. Thereafter, pre-baking was carried out at 100° C. for 90 seconds to evaporate the solvent from the first resist film. The resist film after the pre-baking had a thickness of about 1.0 μm.

Next, the resist film was exposed to light by use of a stepper, made by Nikon Corporation. Thereafter, the PEB treatment was carried out at 110° C. for 60 seconds, followed by development with an alkaline aqueous developer (HMD3, made by Tokyo Ohka Kogyo Co., Ltd.) to obtain a resist pattern.

### Example 4

For a resist composition, a chemically amplified excimer resist, made by Tokyo Ohka Kogyo Co., Ltd., was used. Next, the resist composition was dropped on a silicon wafer and spin coated by use of a spinner. Thereafter, pre-baking was carried out at 90° C. for 90 seconds to evaporate the solvent from the first resist film. The resist film after the pre-baking had a thickness of about 0.8 μm.

Next, the resist film was exposed to light by use of a KrF excimer reduced projection-type aligner. Thereafter, the PEB treatment was carried out at 100° C. for 90 seconds, followed by development with an alkaline aqueous developer of TMAH (NMD-W, made by Tokyo Ohka Kogyo Co., Ltd.) to obtain a resist pattern.

### Example 5

For a resist composition, a chemical amplification-type resist (MELKER, J. Vac. Sci. Technol., B11 (6) 2773, 1993), made by Ryouden Chemicals, Ltd., containing t-butoxycarbonylated polyhydroxystyrene and an acid generator was used. Next, the resist composition was dropped on a silicon wafer and spin coated by use of a spinner. Thereafter, pre-baking was carried out at 120° C. for 180 seconds to evaporate the solvent from the first resist film. The resist film after the pre-baking had a thickness of about 0.52 μm.

Next, for the purpose of forming an antistatic film, Espacer ESP 100, made by Showa Denko K.K., was dropped on the resist film and spin coated by use of a spinner. Thereafter, pre-baking was carried out at 80° C. for 120 seconds.

Next, an EB writing device was used for writing at a dosage of 17.4 μC/cm². Thereafter the PEB treatment was carried out at 80° C. for 120 seconds, after which the antistatic film was removed by use of pure water, followed by development with an alkaline aqueous developer of TMAH (NMD-W, made by Tokyo Ohka Kogyo Co., Ltd.) to obtain a resist pattern. The resulting resist pattern had a thickness of about 0.2 μm.

Preparation of Micropattern Forming Material

### Example 6

400 g of pure water was added to an aqueous solution of 20 wt % of a copolymer of p-(1,2-dihydroxy-1,2-dimethylpropyl)styrene and tetramethylammonium-p-styrenesulfonate and mixed under agitation at room temperature for 6 hours to obtain an aqueous solution of 5 wt % of the water-soluble resin. 100 ppm of a surface active agent was further added to the solution to provide a micropattern forming material.

### Example 7

400 g of an aqueous solution containing 20 wt % of hydrobenzoin was added to an aqueous solution of 20 wt % of polyvinyl alcohol and mixed under agitation at room temperature for 6 hours to obtain a mixed solution of 5 wt % of polyvinyl alcohol and hydrobenzoin. 100 ppm of a surface active agent was added to the mixed solution to obtain a micropattern forming material.

Formation of Micropatterns

### Example 8

The micropattern forming material obtained in Example 6 was dropped on the silicon wafer obtained in Example 3, on which the resist pattern had been formed, and spin coated by use of a spinner. Thereafter, a hot plate was used for pre-baking at 85° C. for 70 seconds to obtain a micropattern forming film.

Next, a hot plate was used to carry out the MB treatment at 120° C. for 90 seconds to permit an insolubilization reaction to proceed in the micropattern forming film. Thereafter, pure water was used for development to remove a non-insolubilized layer of the micropattern forming film. Subsequently, a hot plate was used for post-baking at 90° C. for 90 seconds to form a micropattern on the resin pattern.

### Example 9

The micropattern forming material obtained in Example 6 was dropped on the silicon wafer obtained in Example 2 and forming the resist pattern thereon and spin coated by use of a spinner. Thereafter, a hot plate was used for pre-baking at 85° C. for 70 seconds to form a micropattern forming film.

Next, the wafer was exposed to over the entire surfaces thereof by use of an i-line aligner. Thereafter, a hot plate was used for the MB treatment at 150° C. for 90 seconds to permit the insolubilization reaction to proceed in the micropattern forming film.

Pure water was used to carry out development treatment thereby removing a non-insolubilized layer of the micropattern forming film. Subsequently, a hot plate was used for post-baking at 110° C. for 90 seconds to form a micropattern on the resist pattern.

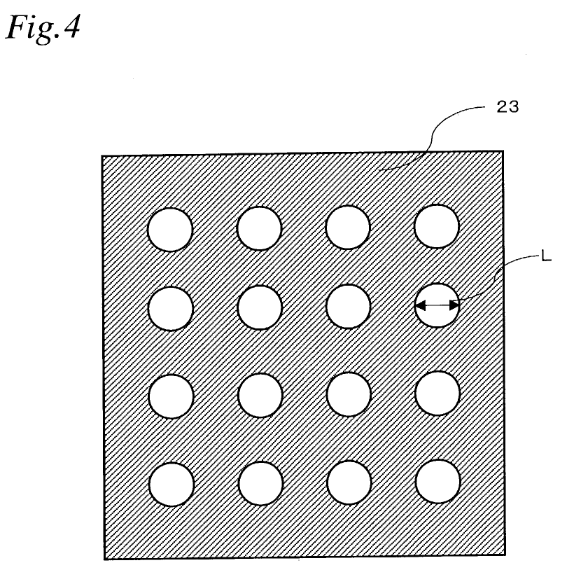

The patterns formed according to the examples are illustrated with reference to FIG. 4. In FIG. 4, a shaded area indicates a portion where a micropattern 23 is formed. The measurement of a hole diameter L in the figure reveals that it was at about 0.26 μm, which was reduced by about 0.14 μm relative to a hole diameter L prior to the formation of the insolubilized layer. On the other hand, a hole diameter L in case where the MB treatment was carried out without exposure to light was found to be at about 0.29 μm, which was reduced by about 0.11 μm relative to a hole diameter L prior to the formation of the insolubilized layer.

### Example 10

An electron beam was irradiated selectively by use of an electron beam shield on the silicon wafer obtained in Example 2 and forming the resist pattern thereon. The dosage was at 50 μC/cm². Next, the micropattern forming material obtained in Example 6 was dropped on the wafer and spin coated by use of a spinner. Thereafter, a hot plate was used for pre-baking at 85° C. for 70 seconds to form a micropattern forming film.

Next, a hot plate was used for the MB treatment at 120° C. for 90 seconds to permit the insolubilization reaction to proceed in the micropattern forming film.

Next, pure water was used for development to remove a non-insolubilized layer of the micropattern forming film. Subsequently, a hot plate was used for post-baking at 110° C. for 70 seconds to selectively form a micropattern on the resist pattern.

The patterns formed in these examples are illustrated with reference to FIG. 4. In FIG. 4, the shaded area indicates a portion where the micropattern 23 is formed. The hole diameters L of the figure were measured at the portion irradiated with an electron beam and a portion not irradiated with an electron beam, revealing that the hole diameter L at the portion irradiated with an electron beam was the same as the hole diameter L prior to the formation of the insolubilized layer. On the other hand, the hole diameter L at the portion not irradiated with an electron beams was reduced over the hole diameter L prior to the formation of the insolubilized layer.

The features and advantages of the present invention may be summarized as follows.

According to one aspect, a micropattern forming film was insolubilized at the interface between a resist pattern and the micropattern forming film, after which a non-insolubilized micropattern forming film is removed, so that a fine pattern can be formed beyond the limit of an exposure wavelength.

According to another aspect, the insolubilization of the micropattern forming film is realized by using the polar change ascribed to the pinacol rearrangement, and the internal stress generated in the resist can be reduced, thus enabling one to prevent the deformation of the resist pattern.

According to another aspect, an aromatic ring-containing micropattern forming film is formed on the resist pattern so as to cover the resist pattern therewith, so that the resist pattern is prevented from attacking with an etchant, thereby forming a pattern of high precision in underlying thin films.

According to another aspect, the insolubilization reaction of the micropattern is more facilitated by exposure to light prior to the MB treatment, and thus the insolubilized layer can be formed in a larger thickness, thereby ensuring the formation of a finer pattern.

Moreover, according to other aspect, only a selected area of a support is exposed or is irradiated with an electron beam, so that micropatterns of different dimensions can be formed on the same support.

For further reference, the micropattern forming material and the micropattern forming method according to the present invention may be summarized as follows.

According to one aspect, the resist pattern is made of a resist containing a novolac resin and a naphthoquinone diazide photosensitive agent.

According to another aspect, the resist pattern is made of a chemically amplified resist.

According to another aspect, the micropattern forming material further comprises a surface active agent.

According to another aspect, the resist pattern is formed of a resist capable of generating an acid by thermal treatment. According to another aspect, the resist pattern is formed of a resist capable of generating an acid by exposure to light.

According to another aspect, the resist pattern is formed of a resist containing an acid.

According to other aspect, the second step is carried out after the resist pattern formed by the first step is surface-treated with an acid liquid or an acid gas.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-230113, filed on Aug. 7, 2002 including specification, claims, drawings and summary, on which the Convention priority of the present application is based, are incorporated herein by reference in its entirety.

What is claimed is:

1. A micropattern forming material, comprising:
a polar change material formed on a resist pattern capable of generating an acid, said polar change material being soluble in water or an alkali, a portion of said polar change material in contact with said resist pattern undergoing a polar change caused by the acid from said resist pattern to form an insolubilized film insoluble in at least one of water and the alkali; and
water or a mixed solvent of water and a water-soluble organic solvent.

2. The micropattern forming material according to claim 1, wherein said polar change material includes:
a resin soluble in water or the alkali; and
a pinacol.

3. The micropattern forming material according to claim 2, wherein said resin has a structure containing an aromatic ring in the molecule.

4. The micropattern forming material according to claim 2, wherein said resin is at least one selected from the group consisting of polyvinyl alcohol, polyacrylic acid, polyvinyl acetal, polyvinyl pyrrolidone, polyethyleneimine, polyethylene oxide, a styrene-maleic anhydride copolymer, polyvinylamine, polyallylamine, an oxazoline group-containing water-soluble resin, a water-soluble melamine resin, a water-soluble urea resin, an alkyd resin and a sulfonamide.

5. The micropattern forming material according to claim 2, wherein said pinacol is selected from the group consisting of 1,1,2,2-tetramethylethylene glycol, hydrobenzoin, benzopinacol, DL-α,β-di-(4-pyridyl) glycol and 2,3-di-2-pyridyl-2,3-butanediol.

6. The micropattern forming material according to claim 1, wherein said polar change material includes a copolymer containing a pinacol component.

7. The micropattern forming material according to claim 6, wherein said copolymer consists of a copolymer of p-(1,2-dihydroxy-1,2-dimethylpropyl)styrene and a hydrophilic group-containing styrene derivative.

8. The micropattern forming material according to claim 7, wherein said hydrophilic group-containing styrene derivative consists of tetramethylammonium-p-styrenesulfonate and/or styrene having an ethylene oxide oligomer at the para position.

9. The micropattern forming material according to claim 1, further comprising a surface active agent.

10. A micropattern forming method comprising the steps of:
forming a resist pattern capable of generating an acid on a support;
coating a micropattern forming material soluble in water or an alkali on said resist pattern to form a micropattern forming film, said micropattern forming material including (i) a polar change material soluble in water or the alkali undergoing a polar change caused by the acid, and (ii) water or a mixed solvent of water and a water-soluble organic solvent;
forming an insolubilized film by the polar change of said micropattern forming film caused by the acid from said resist pattern at a portion of said micropattern forming film in contact with said resist pattern, said insolubilized film being insoluble in at least one of water and the alkali; and
removing the remaining portion of said micropattern forming film which is soluble in water or the alkali.

11. The micropattern forming method according to claim 10, wherein said polar change material includes:
a resin soluble in water or the alkali; and
a pinacol.

12. The micropattern forming method according to claim 11, wherein a thickness of said insolubilized film is controlled by changing a mixing ratio of said resin and said pinacol.

13. The micropattern forming method according to claim 10, wherein said polar change material includes a copolymer containing a pinacol component.

14. The micropattern forming method according to claim 13, wherein a thickness of said insolubilized film is controlled by changing a copolymerization ratio between said pinacol component and the other component constituting said copolymer.

15. The micropattern forming method according to claim 10, wherein said step of forming the insolubilized film includes a thermally treating step.

16. The micropattern forming method according to claim 15, wherein said step of forming the insolubilized film further includes an exposure step.

17. The micropattern forming method according to claim 10, wherein said step of forming the insolubilized film includes a step of irradiating an irradiation light on a selected region of said resist pattern by using a mask, and the irradiation light causes said resist pattern to generate the acid.

18. The micropattern forming method according to claim 10, wherein said step of coating the micropattern forming material is carried out after an electron beam is selectively irradiated on said resist pattern by using a mask to exposed a pattern of said mask.

19. The micropattern forming method according to claim 10, wherein said support is a semiconductor substrate.

20. The micropattern forming method according to claim 10, wherein said resist pattern is made of a resist containing a novolac resin and a naphthoquinone diazid photosensitive agent.

21. The micropattern forming method according to claim 10, wherein said resist pattern is made of a chemically amplified resist.

22. The micropattern forming method according to claim 10, wherein said resist pattern is surface-treated with an acidic liquid or an acidic gas, followed by said step of coating the micropattern forming material.
